(19) United States
(12) Patent Application Publication
(10) Pub. No.: US 2024/0304410 A1
(43) Pub. Date: Sep. 12, 2024

(54) ELECTRON BEAM MICROSCOPE

(71) Applicant: Carl Zeiss Microscopy GmbH, Jena (DE)

(72) Inventor: Erik Essers, Aalen (DE)

(21) Appl. No.: 18/600,212

(22) Filed: Mar. 8, 2024

(30) Foreign Application Priority Data
Mar. 10, 2023 (DE) 10 2023 106 030.9

(51) Int. Cl. H01J 37/26; H01J 37/14; H01J 37/147; H01J 37/244

(52) U.S. Cl. CPC H01J 37/26; H01J 37/14; H01J 37/147; H01J 37/244; H01J 2237/049; H01J 2237/141; H01J 2237/1415; H01J 2237/2443

(57) ABSTRACT

An electron beam microscope comprises an electron beam source, a beam tube, a magnetic objective lens, an object holder, a scintillator arrangement, a detector arrangement and a potential supply system. The power supply system supplies: i) the object holder with a potential U1; ii) the beam tube with a potential U2; iii) a pole end of the objective lens with a potential U3; iv) a scintillator body of the scintillator arrangement with a potential; and v) a light detector of the detector arrangement with a potential U5, such that:

$$( U 2 - U 5 ) \geq 5000 V ;$$

$$( U 4 - U 1 ) \geq 0.1 * ( U 2 - U 1 )$$

$$\vert U 4 - U 5 \vert \geq 0.1 * ( U 2 - U 1 ) , and$$

$$\vert U 3 - U 5 \vert \leq 0.3 * ( U 2 - U 1 ) .$$

### CROSS-REFERENCE TO RELATED APPLICATION

This application claims benefit under 35 U.S.C. § 119 to German Application No. 10 2023 106 030.9, filed Mar. 10, 2023. The entire disclosure of this application is incorporated by reference herein.

### FIELD

The disclosure relates to electron beam microscopes, such as electron beam microscopes which comprise an electron beam source, a beam tube, a magnetic objective lens, an object holder and a detection system for electrons. The electron beam source generates an electron beam whose electrons are accelerated, enter the beam tube at one end, exit it at the other end and are incident on an object held at the object holder. The magnetic objective lens focuses the electron beam in an object plane in which a surface of the object is arranged. The electron beam that is incident on the object generates electrons that leave the object, such as secondary electrons and backscatter electrons whose intensity is detected. The intensity detected allows conclusions to be drawn about the structure of the object at the location where the electron beam appears on the object. The detection of the electrons takes place using the detection system which comprises a scintillator arrangement and a detector arrangement for light generated by the scintillator arrangement. The scintillator arrangement comprises a scintillator body, which generates light from electrons that are incident on the scintillator body and penetrate it, by converting part of the kinetic energy of the electrons into light. This light is detected by a light detector of the detector arrangement in which, upon the incidence of light, generates electrical signals, which can be evaluated by a controller.

### BACKGROUND

In some situations, it is desirable to detect a large proportion of the backscatter electrons generated in the object. These can have a higher kinetic energy when emerging from the object compared with the secondary electrons that are also generated. Between the end of the beam tube near the object plane and the object plane, there can be electrostatic fields, which decelerate the electrons of the electron beam passing through the beam tube with high kinetic energy before they are incident on the object and which contribute to the focusing of the electron beam in the object plane and which also accelerate the electrons generated at the object away from it. In this case, the secondary electrons emerging from the object divergently can be not only accelerated away from the object, but can also be partially focused into the beam tube so that they can be detected by a detector arranged in the beam tube. The electric fields can have a comparatively lesser focusing effect on the backscatter electrons generated at the object, with the result that the backscatter electrons may move further away from an axis of symmetry of the objective lens, only some of them enter the beam tube and they cannot be detected efficiently by a detector arranged in the beam tube. In order to detect these backscatter electrons, an electron detector, which is arranged in a region near the object plane and near the end of the beam tube from which the electron beam exits, could be used.

U.S. pat. No. 9,029,766 B2 discloses an electron beam microscope of this type, which comprises a scintillator arrangement with a scintillator body arranged near the object. The light generated by electrons incident on the scintillator body is directed to a light detector arranged outside the objective lens via a light guide extending through the pole ends of a magnetic objective lens.

### SUMMARY

It has been shown that this conventionally known electron microscope does not meet expected desired properties.

The present disclosure proposes an electron beam microscope which comprises an electron beam source, a beam tube, a magnetic objective lens and a scintillator arrangement near an object plane and exhibits improved properties.

According to an aspect of the disclosure, an electron beam microscope comprises an electron beam source, a beam tube, a magnetic objective lens, an object holder, a scintillator arrangement and a detector arrangement having at least one light detector. The electron beam source is configured to generate an electron beam whose electrons are accelerated to a high kinetic energy before they enter the beam tube. The electron beam enters the beam tube at a first end and exits it at a second end. The beam tube is an electrode which surrounds the electron beam and is at a given electric potential which is selected relative to the potential of the electron emitter of the electron beam source in such a way that the electrons entering the beam tube quickly cover the distance between the first end of the beam tube, which is arranged near the electron source, and the second end of the beam tube, which is located near the object holder. The beam tube does not necessarily have a straight-line circular tube shape. Rather, the diameter of the electrode may vary along the path, the cross section of the electrode does not need to be round everywhere, the electrode may have cutouts or windows, and other components, such as a detector, may be arranged within the beam tube. In addition, the beam tube can include other components, such as a condenser lens or the entire objective lens or a part of the latter. The beam tube can be self-supporting, such that, for example, a metallic tube with its inner shell surface provides the electrode and at the same time also the electrode-bearing structure. However, the beam tube may also at least partially not be self-supporting, for example if the electrode is provided by a thin metallic layer which is supported on an inner wall of a carrier, such as a tube of electrically insulating plastic, for example. The magnetic objective lens is used to focus the electron beam in an object plane. The magnetic objective lens comprises a solenoid and a yoke with two pole ends, each extending around an axis of symmetry of the magnetic objective lens. Current flowing through the solenoid generates a magnetic field that exits the yoke at the pole ends and has a focusing effect on the electron beam.

The object holder is configured to hold an object to be examined with the electron beam microscope in such a way that its surface is arranged in the object plane.

The scintillator arrangement comprises at least one scintillator body, which is configured to generate light from electrons coming from the object plane. The scintillator arrangement has at least one light exit surface through which the light generated by the scintillator body exits the scintillator arrangement into a vacuum space. The at least one light detector is configured to convert the light emerging from the light exit surface of the scintillator arrangement into electrical signals, wherein the detector arrangement has at least one light entry surface through which the light enters the detector arrangement from the vacuum space in order to be detected by the light detector.

According to exemplary embodiments, the electron beam microscope comprises a potential supply system, which is configured to supply the object holder with a first potential U1, to supply the beam tube with a second potential U2, to supply at least one of the pole ends with a third potential U3, to supply the at least one scintillator body of the scintillator arrangement with a fourth potential U4 and to supply the light detector with a fifth potential U5. One or more of the following relations (1) to (5) may apply:

$$( U 2 - U 5 ) \geq 5000 V \qquad ( 1 )$$

$$( U 4 - U 1 ) \geq 0.1 * ( U 2 - U 1 ) \qquad ( 2 )$$

$$\vert U 4 - U 5 \vert \geq 0.1 * ( U 2 - U 1 ) \qquad ( 3 )$$

$$\vert U 3 - U 5 \vert \leq 0.3 * ( U 2 - U 1 ) \qquad ( 4 )$$

$$\vert U 2 - U 4 \vert \geq 0.1 * ( U 2 - U 1 ) \qquad ( 5 )$$

Assuming that the potential U5 of the light detector and the potential of the electronics provided for the operation of the light detector are close to ground potential, the relation (1) states that the potential U2 of the beam tube is significantly different from the ground potential. In the case that the object is also at a potential U1 which is not too different from the ground potential, the relation (1) states that the kinetic energy of the electrons of the electron beam between the end of the beam tube from which they exit, and the object is reduced by at least 5 keV, i.e. the electrons are significantly decelerated before they are incident on the object. The kinetic energy with which the electrons are incident on the object is determined by the difference between the potential of the electron beam source and the potential U1 of the object holder. Conversely, electrons that emerge from the object and enter the beam tube are accelerated accordingly.

According to exemplary embodiments, the following may also apply: (U2−βU5)≥3000 V, (U2−U5)≥7000 V or (U2−U5)≥9000 V, and furthermore (U2-U5)<35 000 V, (U2−U5)<20 000 V or (U2−U5)<10 000 V.

The relation (2) states that the scintillator body of the scintillator arrangement and the object are at clearly different potentials. In particular, the scintillator body may be at a potential that lies between the potentials of the beam tube and the object. Also, the scintillator body of the scintillator arrangement can thus be used to shape the electrostatic field between the object and the near-object end of the beam tube.

According to exemplary embodiments, the following may also apply: (U4−U1)≥0.2*(U2−U1) or (U4−U1)≥0.3*(U2−U1).

The relation (3) states that the scintillator body of the scintillator arrangement and the detector arrangement are at significantly different potentials. Since the scintillator body and the detector arrangement are separated by the vacuum space, through which the light that emerges from the light exit surface of the scintillator arrangement and enters the light entry surface of the detector arrangement passes, this vacuum space provides an insulation between the scintillator arrangement and the detector arrangement. Due to this insulation, the potential U5 can be selected for the detector arrangement according to criteria that are independent of the provision of the electrostatic fields influencing the electrons of the electron beam and the electrons emerging at the object. Rather, the potential U5 can be selected according to criteria which are, among other things, due to constructive conditions of the objective lens and take into account, for example, the routing of electrical lines to the detector arrangement. The potential of the light exit surface of the scintillator arrangement may be equal to that of the scintillator body of the scintillator arrangement or different therefrom.

According to exemplary embodiments, the following may also apply: |U4−U5|≥0.2*(U2−U1) or |U4−U5|≥0.3*(U2−U1).

The relation (4) states that the potential difference between the detector arrangement and the at least one pole end is small so that the potential of the detector arrangement can be close to the potential of a main body of the objective lens, which simplifies construction, since no complex electrical insulations and creepage distances need to be provided between the objective lens and the detector arrangement and the supply lines thereof.

According to exemplary embodiments, the following may also apply: |U3−U5|≤0.2*(U2−U1) or |U3−U5|≤0.1*(U2−U1)

The relation (5) states that the potential difference between the scintillator body and the beam tube is significant so that electric fields can be generated both between the scintillator body and the beam tube and between the scintillator body and the object, which fields together contribute to the deceleration of the electrons of the electron beam on the way to the object and to the acceleration of the electrons generated at the object away from the object and towards the objective lens and the scintillator arrangement.

According to exemplary embodiments, the following may also apply: (U2−U4)≥0.2*(U2−U1) or (U2−U4)≥0.3*(U2−U1)

According to exemplary embodiments, the scintillator arrangement and the detector arrangement are arranged within the objective lens. This is the case, for example, when a smallest envelope surrounding the yoke of the objective lens with its two pole ends also surrounds the scintillator arrangement and the detector arrangement.

According to exemplary embodiments, the electron beam microscope comprises a mirror with a light reflecting mirror surface, which is designed such that it reflects the light emerging from the at least one light exit surface of the scintillator arrangement towards the at least one light entry surface of the detector arrangement. The mirror allows the beam path between the light exit surface and the light entry surface to be folded, as a result of which degrees of freedom are provided for the design of the electron beam microscope, by virtue of the fact that the light exit surface and the light entry surface do not have to be directly opposite each other. Furthermore, the mirror allows an increased detection efficiency for electrons by virtue of the fact that a larger proportion of the light emerging from the light exit surface reaches the light entry surface with the aid of the mirror.

According to exemplary embodiments, the mirror surface may at least partially have a symmetrical shape with respect to the axis of symmetry of the objective lens.

According to exemplary embodiments, the mirror surface has a shape which, viewed in a cross section containing the axis of symmetry of the objective lens, is part of an ellipse. Consequently, light which emerges from the light exit surface of the scintillator arrangement divergently can be collimated or focused in the direction of the light entry surface of the detector arrangement such that a larger proportion of the light emerging from the light exit surface enters the light entry surface and can be detected by the light detector or the installation space used for the detector arrangement can be reduced.

According to exemplary embodiments, the ellipse has a first focal point and a second focal point, wherein the first focal point is arranged closer to the light exit surface than to the light entry surface and wherein the second focal point is arranged closer to the light entry surface than to the light exit surface. Consequently, the proportion of the light that emerges from the scintillator arrangement and is detected by the detector arrangement can be increased.

According to exemplary embodiments, one of the two pole ends, viewed in a cross section containing the axis of symmetry, is arranged closer to the beam tube than the other of the two pole ends, and the mirror is carried at the pole end which is further away from the beam tube. According to further exemplary embodiments, at least a part of the mirror surface is arranged at a smaller distance from the object plane than the at least one light exit surface of the scintillator arrangement.

According to exemplary embodiments, the scintillator arrangement, viewed in a cross section containing the axis of symmetry, comprises two scintillator bodies arranged side by side, and the detector arrangement, viewed in this cross section, comprises two light detectors arranged side by side. In the cross section containing the axis of symmetry, the two scintillator bodies or the two light detectors can thus be arranged offset to each other in the direction of the axis of symmetry and/or perpendicular to the axis of symmetry. The two scintillator bodies are impinged upon by electrons, which, viewed in a cross section containing the axis of symmetry, emanate from the object plane at different angles or with different kinetic energies. The electrons emanating from the object plane at different angles from different angle ranges or with different kinetic energies from different energy ranges thus generate light in different scintillator bodies. This light can be detected in the two light detectors which are assigned to the two scintillator bodies, so that it is possible to discriminate the detected electrons with regard to their angle ranges or ranges of their kinetic energy via the detection signals. The two light detectors can be configured here in such a way that substantially only the light that emerges from the light exit surface of one scintillator body is incident on the light entry surface of the one light detector, and substantially only the light that emerges from the light exit surface of the other scintillator body is incident on the light entry surface of the other light detector.

According to exemplary embodiments, the scintillator arrangement comprises at least one light guide, which is optically coupled to the at least one scintillator body and which provides the at least one light exit surface from which the light that is generated in the scintillator body and is incident on the light entry surface of the detector arrangement emerges. This makes it possible to select the position of the scintillator body for a desired detection of electrons and to select the position of the light exit surface in such a way that, regardless of the position of the scintillator body itself, a large proportion of the light emerging from the light exit surface reaches the light entry surface of the light detector. According to exemplary embodiments herein, at least one surface of the light guide, which is different from the light exit surface and from a surface coupled to the scintillator body, is provided with a layer of metal. This increases the proportion of light that passes from the scintillator body into the light guide and emerges at the light exit surface of the light guide.

According to exemplary embodiments, at least a part of the surface of the scintillator body is provided with an electrically conductive layer. As a result, these surfaces of the scintillator body are at a defined potential and do not charge electrically due to incident electrons. In particular, the light exit surface of the scintillator arrangement may be provided with an electrically conductive layer, which is light-transmissive. Such a layer may, for example, comprise or consist of a composition comprising indium and tin oxide.

According to exemplary embodiments, the at least one light detector is carried at one of the two pole ends. In particular, the light detector may be carried at the pole end which is further away from the beam tube in comparison with the other pole end.

According to exemplary embodiments, the at least one scintillator body is arranged closer to the object plane than the at least one light entry surface of the detector arrangement.

According to exemplary embodiments, the at least one scintillator body is carried at the beam tube or a carrier of the beam tube.

According to exemplary embodiments, the electron beam microscope comprises a further electron detector, which is configured to detect electrons that are coming from the object plane and have entered the beam tube at the second end of the beam tube. This further electron detector can substantially detect secondary electrons, which, as explained above, enter the beam tube to a greater portion than do backscatter electrons, while substantially backscatter electrons can be detected via the scintillator arrangement and detector arrangement.

The electron beam microscope may further comprise beam deflectors, which are configured to vary a location of incidence of the electron beam on the object plane and to scan the electron beam over the object plane, wherein the beam deflector, viewed along the axis of symmetry, is arranged between the further detector and the object plane. Further, the beam deflector, viewed along the axis of symmetry, may be arranged between the further electron detector and the at least one scintillator body.

According to exemplary embodiments, the detector arrangement comprises a plurality of scintillator bodies and/or light detectors distributed around the axis of symmetry of the objective lens. This makes it possible to discriminate electrons emerging from the object plane with regard to their azimuth angle about the axis of symmetry and, in particular, to conduct stereoscopic examinations.

According to exemplary embodiments, the scintillator arrangement comprises a single scintillator body having a torus shape surrounding the axis of symmetry. According to other exemplary embodiments, the scintillator arrangement comprises a plurality of scintillator bodies distributed around the axis of symmetry. The plurality of scintillator bodies can then together form a torus shape.

According to exemplary embodiments, a plane which passes through an intersection point between the object plane and the axis of symmetry and which touches but does not intersect an outer edge of the objective lens extends to the axis of symmetry at an angle of less than 50°. This means that the objective lens has a substantially conical shape, the cone angle of which is small, with the result that large-scale objects whose surfaces are strongly tilted relative to the axis of symmetry and to the electron beam can be examined with the electron beam microscope. It is often desirable to examine objects that are strongly tilted. However, the small cone angle of the objective lens imposes high demands regarding the design of the objective lens. In particular, there is little available installation space within the objective lens near the object plane. The embodiment of the electron microscope described here enables the placement of the detection system, formed by the scintillator arrangement and the detector arrangement, within the objective lens with a small installation space.

According to exemplary embodiments, the electron microscope comprises a ring electrode with a hole symmetrical with respect to the axis of symmetry, wherein the ring electrode, viewed along the axis of symmetry, is arranged between the scintillator body and the object plane. The ring electrode can be supplied with an electric potential by the potential supply system in such a way that the ring electrode also contributes to the formation of the electric field between the beam tube and the object plane. In particular, the ring electrode may be electrically connected to that pole end of the two pole ends to which the potential U3 is supplied. Further, the ring electrode may be carried at that pole end of the two pole ends which, viewed in a cross section containing the axis of symmetry, is further away from the beam tube.

According to exemplary embodiments, the hole in the ring electrode has a radius greater than a smallest distance of the at least one scintillator body from the axis of symmetry. If a single scintillator body is provided, which has a central hole, the diameter of this hole may be smaller than the diameter of the hole in the ring electrode. In particular, if a plurality of scintillator bodies are provided which are distributed around the axis of symmetry, it is not necessary that the scintillator bodies are delimited inwardly, towards the axis of symmetry, in a circular manner. Rather, the plurality of scintillator bodies can delimit a cross-sectional area which contains the axis of symmetry and which, for example, has a polygonal shape, the sections of which have a smallest distance from the axis of symmetry that is smaller than the radius of the ring electrode. In this way, the ring electrode can contribute to the shaping of the electric fields between the beam tube and the object plane, without too many electrons emanating from the object being incident on the ring electrode and not on the scintillator body and thus not being able to be detected.

According to exemplary embodiments, the scintillator arrangement and the light entry surface of the detector arrangement are arranged relative to each other such that light generated by the electron beam at the object is not directly incident on the light entry surface and the scintillator arrangement thus shadows the light entry surface for this light. This can prevent light generated by the electron beam at the object, such as cathodoluminescence radiation, from generating detection signals that could be assumed to be due to backscatter electrons.

Embodiments of the disclosure will be explained in more detail below with reference to figures.

### BRIEF DESCRIPTION OF THE DRAWINGS

FIG. 1 shows a schematic sectional view of an electron beam microscope according to a first embodiment.

FIG. 2 shows in a partial view of FIG. 1 the details of an objective lens of the electron beam microscope shown in FIG. 1.

FIG. 3 shows a schematic sectional view of details of an objective lens of an electron beam microscope corresponding to FIG. 2, according to a second embodiment.

FIG. 4 shows a schematic sectional view of details of an objective lens of an electron beam microscope corresponding to FIG. 2, according to a third embodiment.

### DETAILED DESCRIPTION

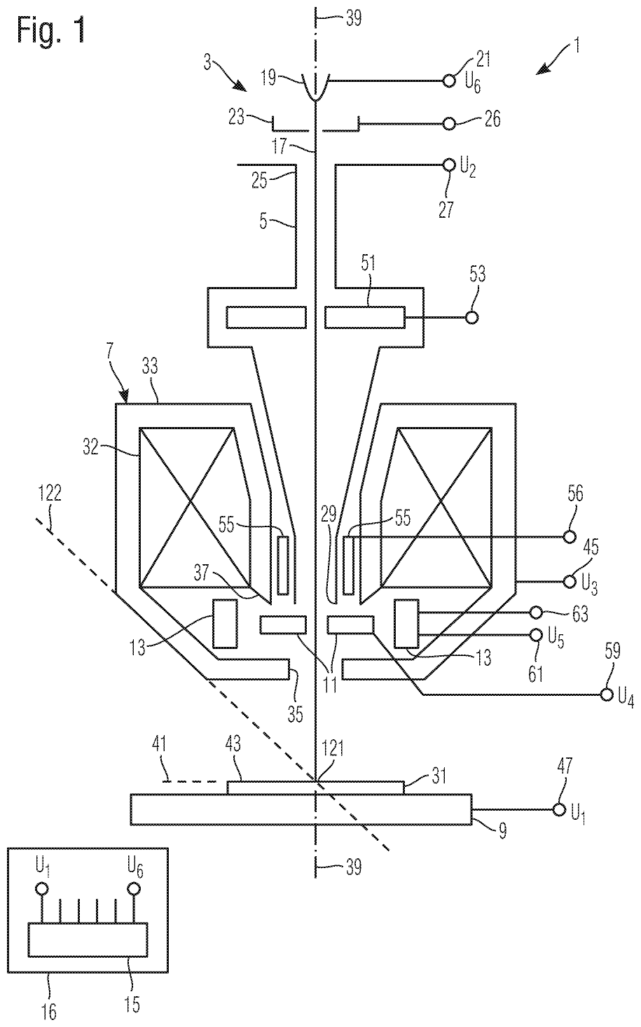

FIG. 1 shows a schematic sectional view of an electron beam microscope 1 according to a first embodiment. The electron beam microscope 1 comprises an electron beam source 3, a beam tube 5, a magnetic objective lens 7, an object holder 9, a scintillator arrangement 11, a detector arrangement 13 and a potential supply system 15, which is part of a controller 16 of the electron beam microscope 1.

The electron beam source 3 is configured to generate an electron beam 17. For this purpose, the electron beam source 3 comprises an electron emitter 19, which is supplied with an electric potential U6 by the potential supply system 15 via a terminal 21. The electron beam source 3 further comprises an extractor 23, which is supplied with a suitable electric potential by the potential supply system 15 via a terminal 26 to extract electrons from the electron emitter 19 and to shape the electron beam 17 which passes through a hole in the extractor 23 such that it enters an upper end 25 of the beam tube 5.

The beam tube 5 is supplied with an electric potential U2 by the potential supply system 15 via a terminal 27 such that the electrons of the electron beam 17 between the electron emitter 19 and the upper end 25 of the beam tube 5 are accelerated and enter the beam tube 5 with high kinetic energy. The electrons of the electron beam 17 pass through the beam tube 5 and exit therefrom at a lower end 29 of the beam tube 5 to then be incident on an object 31 held at the object holder 9.

The magnetic objective lens 7 comprises a solenoid 32 within a yoke 33 that surrounds the solenoid 32 and has two pole ends 35 and 37. The two pole ends 35 and 37 extend symmetrically around an axis of symmetry 39 of the magnetic objective lens 7. The two pole ends 35 and 37 are spaced apart so that a magnetic field generated by a current in the solenoid 32 exits from the yoke 33 at the pole ends 35 and 37 and has a focusing effect on the particle beam 17 so that the particle beam 17 is focused in an object plane 41. The object holder 9 is advantageously positioned such that a surface 43 of the object 31 is arranged in the object plane 41. An electric potential U3 is supplied by the potential supply system 15 via a terminal 45 to the pole ends 35, 37, and an electric potential U1 is supplied by the potential supply system 15 via a terminal 47 to the object holder 9.

The difference between the potential U6 of the electron emitter 19 and the potential U1 of the object 31 determines the kinetic energy with which the electrons of the electron beam 17 are incident on the surface 43 of the object 31. This difference can be selected according to the desired properties regarding a desired electron-microscopic examination of the object 31.

For potentials U1 and U2, for example (U2−U1)≥5000 V can apply. This means that the electrons of the electron beam 17 are accelerated by more than 5000 eV between the electron emitter 19 and the upper end 25 of the beam tube 5 and are decelerated by more than 5000 eV between the lower end 29 of the beam tube 5 and the object plane 41. Thus, the electrons of the electric beam 17 pass through the beam tube with an increased kinetic energy and thus correspondingly quickly, with the result that the repulsion of the negatively charged electrons from one another during the drift through the beam tube 5 leads to a comparatively small deterioration in the focusing of the electron beam 17 in the object plane 41.

The electrons of the electron beam 17 generate upon their incidence on the object 31 electrons which emerge from the object 31 in the direction of the objective lens 7. These electrons are accelerated between the lower end 29 of the beam tube 5 and the object plane 41 due to the difference between the potentials U1 and U2. A portion of these electrons can enter the beam tube 5 at its lower end 29 and arrive at an electron detector 51 arranged within the beam tube 5. The electron detector 51 generates from the electrons that are incident thereon electrical signals which are output via a terminal 53 and read by a controller 16 of the electron beam microscope for analysis. The electron detector 51 may comprise, for example, a scintillator body for generating light from the kinetic energy of incident electrons, a light guide coupled to the scintillator body, and a light detector coupled to the light guide, which detects the light generated in the scintillator body and generates the electrical signals. Viewed along the axis of symmetry 39, the location at which electrons are detected using the electron detector 51 lies between the electron beam source 3 and the two pole ends 35 and 37.

The electron beam microscope 1 further comprises beam deflectors 55, which are configured to deflect the electron beam 17 such that it is incident on the surface 43 of the object 31 at selectable sites in the object plane 41. The beam deflectors 55 are connected via a terminal 56 to the controller 16 and are controlled by the latter. In particular, the controller 16 can control the electron microscope 1 in such a way that the location of incidence of the electron beam 17 is scanned over a partial region of the object plane 41 and detection signals of the electron detector 51 are recorded, assigned to the locations of incidence, as data representing an electron-microscopic image of the object.

In addition to the electron detector 51, the electron microscope 1 comprises a further detection system for electrons that are generated by the electron beam 17 at the object 31. This detection system comprises the scintillator arrangement 11 and the detector arrangement 13, which are arranged within the objective lens 7. The scintillator arrangement 11 comprises at least one scintillator body, which is configured to generate light with electrons coming from the object plane 41, wherein the scintillator arrangement has at least one light exit surface, through which the light generated by the scintillator body of the scintillator arrangement 11 can emerge from the scintillator arrangement 11. Details of the scintillator arrangement 11 are described below.

The detector arrangement 13 comprises at least one light detector, which is configured to convert light generated by the scintillator arrangement into electrical signals, wherein the detector arrangement 13 has at least one light entry surface through which the light generated by the scintillator arrangement enters the detector arrangement 13. Details of the detector arrangement 13 are also described further below.

The scintillator arrangement 11, viewed along the axis of symmetry 39, is arranged between the lower end 29 of the beam tube 5 and the object plane 41. The scintillator body of the scintillator arrangement 11 is supplied with an electric potential U4 by the potential supply system 15 via a terminal 59.

For potentials U1 and U4, the above relation (2) may apply, according to which there is a significant potential difference between the scintillator body of the scintillator arrangement 11 and the object 31. This means that, for example, secondary electrons that emerge from the object with small kinetic energies are accelerated by a relatively strong electric field existing between the surface 43 of the object 31 and the scintillator arrangement 11 towards the scintillator arrangement and can pass through a central opening in the scintillator arrangement 11 so as to be detected by the electron detector 51.

The detector arrangement 13 is supplied with an electric potential U5 by the potential supply system 15 via a terminal 61. Detection signals from the light detector are output from the detector arrangement 13 via a terminal 63 and read into the controller 16. Electrons emanating from the object 31 can be incident on the scintillator body of the scintillator arrangement 11 and generate light therein, which is detected by the detector arrangement 13. The corresponding detection signals represent the intensity of the electrons which are generated by the electron beam 17 at the object 31 and are incident on the scintillator body of the scintillator arrangement 11. As from the detection signals of the electron detector 51, data representing an electron-microscopic image of the object 31 can also be obtained from the detection signals of the detector arrangement 13.

The electrons that are incident on the scintillator body of the scintillator arrangement 11 differ from the electrons that are incident on the electron detector 51 substantially in terms of their kinetic energies with which they leave the surface 43 of the object 31. Many of the electrons incident on the electron detector 51 are electrons that only slightly move away from the axis of symmetry 39, pass through a central opening in the scintillator arrangement 11 and enter the beam tube 5 at its lower end 29. In particular when the object 31 is arranged at a short distance from the objective lens 7, many of these electrons are what are known as secondary electrons, which have a kinetic energy of less than 50 eV when released from the surface 43 of the object 31.

The electrons incident on the scintillator body of the scintillator arrangement 11 are those electrons which do not pass through the central opening in the scintillator arrangement 11 because they have moved away from the axis of symmetry 39 by more than corresponds to the radius of the central opening in the scintillator arrangement 11 prior to being incident on the scintillator arrangement 11. These are substantially backscatter electrons, as they are known, whose kinetic energy reaches up to the kinetic energy with which the electrons of the electron beam 17 are incident on the surface of the object 31.

Between the potentials U4 and U5, the above relation (3) may apply, which states that there is a significant potential difference between a scintillator body of the scintillator arrangement 11 and the detector arrangement 13. In particular, if the potential U1 of the object 31 is the ground potential, the potential U4 of the scintillator body of the scintillator arrangement can be a high potential U4 which is suitable for shaping the electric field between the lower end 29 of the beam tube 5 and the object plane 41, while the potential U5 may be closer to the ground potential or the potential U3 of the pole ends 35 and 37. The potential U3 of the pole ends 35, 37 may in particular be equal to the potential U5 of the light detector and/or the potential U1 of the object holder 9.

For potentials U3 and U5, the above relation (4) can apply, which states that the potential difference between the potential U5 of the detector arrangement 13 and the potential U3 of the pole ends 35 and 37 is relatively small. In this situation, it is comparatively easy to route the lines for the terminals 61 and 63 of the detector arrangement 13 within the objective lens 7 and near one of the pole ends 35, 37 or the rest of the yoke 33.

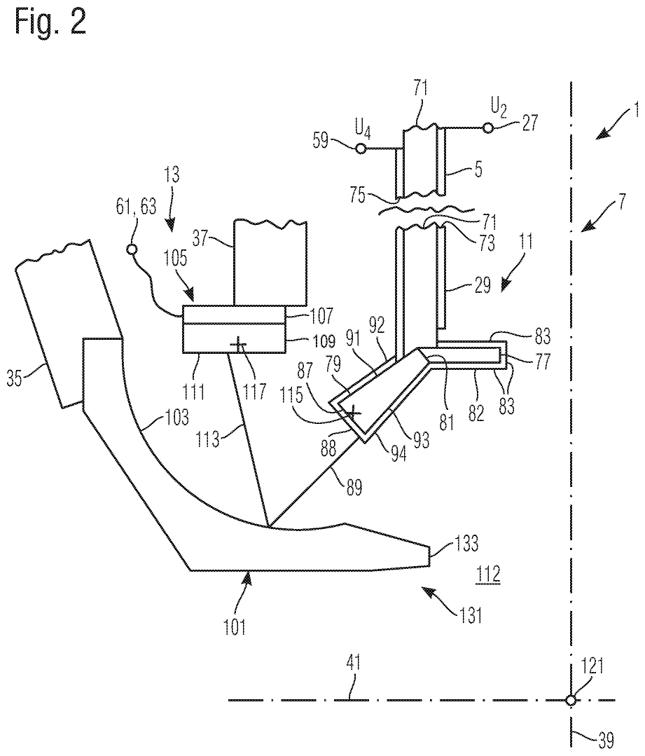

FIG. 2 shows a detailed view of FIG. 1, which in particular shows the left half of the scintillator arrangement 11 and of the detector arrangement 13 in more detail.

The scintillator arrangement 11 is attached near the lower end 29 of the beam tube 5. The beam tube 5, as the electrode surrounding the electron beam, is formed in the region of the lower end 29 of the beam tube 5 as an electrically conductive layer 73, which is mounted on the inner wall of a tube 71 made of an electrically insulating material. The tube 71 is thus a carrier of the electrically conductive layer 73 and thus of the beam tube 5 at the lower end thereof. The electrically conductive layer 73 is electrically connected to the terminal 27, which supplies the beam tube 5 with the electric potential U2, which accelerates the electrons of the electron beam 17 before they enter the beam tube 5 at its upper end 25. The outer wall of the insulating tube 71 is provided with a conductive layer 75, which is connected to the terminal 59 for supplying the electric potential U4 to the scintillator arrangement 11. The terminal 59 may be provided in the illustration of FIG. 1, for example, in a region between the upper end 25 of the beam tube 5 and the objective lens 7.

The scintillator arrangement 11 comprises a scintillator body 77, which is attached near the lower end 29 of the beam tube 5 to the insulating tube 71 and is insulated from the electrically conductive layer 73 and thus from the beam tube 5. The scintillator body 77 has the shape of a torus with plane-parallel main surfaces, with the torus extending around the axis of symmetry 39. It is also possible that instead of the one scintillator body 77, a plurality of sector-type scintillator bodies are provided, which are distributed around the axis of symmetry. The scintillator arrangement 11 further comprises a light guide 79, which is optically coupled to a radially outer surface 81 of the scintillator body 77. Electrons that are incident on the scintillator body 77 and penetrate into it generate light, from which at least a part emerges from the scintillator body 77 via the surface 81 and enters the light guide 79. Other surfaces 83 of the scintillator body 77 may be provided with an electrically conductive reflective layer 82, such as a metal layer, so that light generated in the scintillator body 77 is reflected inside until it passes into the light guide 79 via the surface 81.

The light guide 79 has a surface 87, which is a light exit surface of the scintillator arrangement 11. An exemplary light ray 89 which emerges from the light exit surface 87 of the light guide 79 is shown in FIG. 2. A surface 91 of the light guide 79 is provided with a layer 92 which is electrically conductive and in particular can also be reflective in order to avoid a possible exit of light from this surface 91. The light exit surface 87 of the light guide 79 is provided with an electrically conductive and light-transmissive layer 88. The layer 88 may, for example, comprise or consist of a composition comprising indium and tin oxide.

A further surface 93 of the light guide is provided with a conductive layer 94, which can also be reflective. Via the layers 92, 88 and 94 and the layer 75 on the outer wall of the electrically insulating tube 71, the conductive layers 82 on the surfaces 83 of the scintillator body 77 are connected to the terminal 59, with the result that the surfaces 83 of the scintillator body 77 are at the potential U4, which can be different from the potential U2 of the inner wall 73 of the beam tube 5.

At the lower end of the pole end 35, a mirror 101 is attached, which can be made of metal and is electrically conductively connected to the pole end 35. A part of the surface of the mirror 101 is formed as a mirror surface 103, which reflects the light 89 emerging from the light guide 79 towards the detector arrangement 13. The mirror 101 may be made of a soft-magnetic material to conduct a magnetic flux in the pole end 35 closer to the object plane 41 and to the axis of symmetry 39 such that the mirror 101 forms an extension of the pole end 35 and acts as a part of the objective lens 7 for magnetically focusing the electron beam 17.

Viewed along the axis of symmetry 39, the mirror surface 103 is arranged at least partially between the light exit surface 87 of the scintillator arrangement 11 and the object plane 41 such that a distance between the corresponding part of the mirror surface 103 and the object plane 41 is smaller than a distance between the light exit surface 87 and the object plane 41.

The mirror 101 has an opening 133 which is symmetrical with respect to the axis of symmetry 39 and through which the electron beam 17 passes. The mirror 101, which is at the potential of the pole end 35 in the example described here, contributes to the shaping of the electric fields, which are generated between the object and the lower end 29 of the beam tube 5 and influence the focusing of the electron beam 17 in the object plane 41 and the trajectories of the electrons to be detected. The mirror 101 thus forms a ring electrode 131 through which the electron beam 17 passes.

The beam path of the light rays 89 and 113 between the light exit surface 87 of the scintillator arrangement 11 and the light entry surface 111 of the detector arrangement 13 extends through a vacuum space 112. The vacuum space 112 is located within a vacuum chamber (not shown in the figures). Some of the electron-optical components of the electron beam microscope 1, such as the electron emitter 19, the inner surface of the beam tube 5, the scintillator arrangement 11 and the object 31, are arranged in the vacuum space 112. Other components of the electron beam microscope 1, such as the beam deflectors 55 or the solenoid 32 of the objective lens 7, may be arranged outside the vacuum space 112. In the vacuum space 112 within the vacuum chamber, a vacuum is maintained by the operation of vacuum pumps, which enables the operation of the electron beam source 3 and enables the movement of the electrons of the electron beam 17 and the electrons that emerge from the object and are intended to be detected. This vacuum also electrically insulates the detector arrangement 13 from the light exit surface 87 of the scintillator arrangement 11, such that relatively large potential differences are possible between the two.

The detector arrangement 13 comprises a light detector 105, which is attached to the pole end 37. In the example explained here, the pole end 37 to which the light detector is attached is the pole end of the two pole ends 35, 37 which is arranged closer to the beam tube 5. A distance between the pole end 35 and the beam tube 5 is greater than a distance between the pole end 37 and the beam tube 5.

The light detector 105 comprises a printed circuit board 107, on which a semiconductor detector 109 is mounted, the surface of which that is facing the mirror surface 103 serves as a light entry surface 111 of the detector arrangement 13. FIG. 2 shows, as an exemplary light ray that is incident on the light entry surface 111 of the detector arrangement 13, a light ray 113, which is the light ray 89 reflected at the mirror surface 103. The printed circuit board 107 carries an electric circuit that operates the semiconductor detector 109 and outputs detection signals via the terminal 63.

The light detector 105 attached to the pole end 37 can be electrically conductively connected to the pole end 37 such that the potential of the surfaces of the light detector 105 is substantially the same potential as that of the pole end 37. However, it is also possible that the light detector 105 is electrically insulated from the pole end 37 and the light detector 105 is supplied with the potential U5, which is different from the potential of the pole end 37, via the terminal 61. The potential difference between the detector arrangement 13 and the pole end 37 is either zero or sufficiently small so that connecting wires for the terminals 61 and 63 can be easily guided through the objective lens 7.

In the sectional illustration of FIG. 2, which contains the axis of symmetry 39, the mirror surface 103 has an elliptical shape. This means that the mirror surface is part of an ellipse located in the plane containing the axis of symmetry 39. This ellipse has two spaced-apart focal points 115 and 117, wherein one focal point 115 is close to the light exit surface 87 of the light guide 79 and remote from the light entry surface 111 of the detector arrangement 13, and the other focal point 117 is close to the light entry surface 111 of the detector arrangement 13 and remote from the light exit surface 87 of the scintillator arrangement 11. By designing the mirror surface 103 in this way it is possible to reflect a large part of the light emerging divergently from the light exit surface 87 towards the light entry surface 111 of the detector arrangement 13.

The scintillator body 77, the light guide 79 and the semiconductor detector 109 may each have a ring shape which extends over the entire circumference around the axis of symmetry 39. The mirror surface 103 may also have a ring shape which extends over the entire circumference around the axis of symmetry 39. In this case, the focal points 115 and 117 shown in the cross-sectional view of FIG. 2 are circles, the centres of which lie on the axis of symmetry 39. However, it is also possible that these components, i.e. the scintillator body 77, the light guide 79, the semiconductor detector 109 or the mirror 101, each comprise a plurality of parts, which, viewed over the circumference around the axis of symmetry 39, are joined together. In particular, it is possible that, viewed over the circumference around the axis of symmetry 39, a plurality of mutually separate semiconductor detectors 109 are provided. These correspond to separate light detectors 105 of which each has a terminal 63 for outputting detection signals and for inputting them to the controller 16. With these separate light detectors 105, which can also be referred to as azimuthal detector segments, it is possible to discriminate electrons emerging from the object plane 41 with regard to their azimuthal angle around the axis of symmetry 39 and, in particular, to obtain electron-microscopic images for different azimuthal angles of an object, which can be considered stereoscopic images, for example.

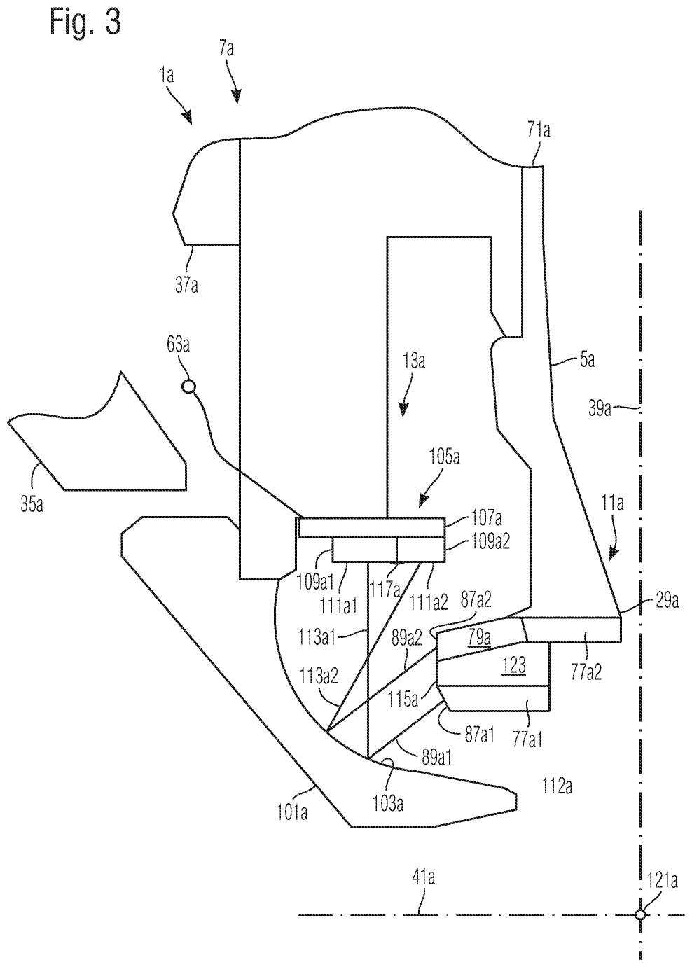

FIG. 3 is a detailed view of an electron microscope la corresponding to FIG. 2, according to a second embodiment. In FIG. 3, components which correspond to those of the first embodiment in terms of their structure or function are provided with the same reference signs as in FIGS. 1 and 2, although a lowercase “a” has been added to the component parts of the second embodiment.

FIG. 3 in turn is a view in a plane containing an axis of symmetry 39a of pole ends 35a and 37a of a magnetic objective lens 7a. A scintillator arrangement 11a is in turn attached to a lower end 29a of a beam tube 5a, and a detector arrangement 13a is attached to a pole end 35a of pole ends 35a and 37a.

The scintillator arrangement 11a comprises in the sectional view of the plane containing the axis of symmetry 39a a first scintillator body 77a1 and a second scintillator body 77a2, which are arranged side-by-side. Due to their different arrangements relative to an intersection point 121a between the axis of symmetry 39a and an object plane 41a, at which the electron beam is focused, electrons which start at different angles relative to the axis of symmetry 39a and/or with different kinetic energies at the point 121a are incident on the two scintillator bodies 77a1 and 77a2.

The first scintillator body 77a1 has a surface 87a1, which provides a first light exit surface of the scintillator arrangement 11a. This means that light generated in the first scintillator body 77a1 exits directly from the first scintillator body 77a1 into the vacuum space 112a without first passing through a light guide. However, it is also possible to provide a light guide at the first light exit surface 87a1 of the scintillator arrangement 11a, which light guide then provides a light exit surface of the scintillator arrangement. The other surfaces of the first scintillator body 77a1, which are different from the light exit surface 87a1, are provided with an electrically conductive and light-reflecting layer, which is not shown in FIG. 3.

A light guide 79a is optically coupled to the second scintillator body 77a2 in order to guide light, which passes from the second scintillator body 77a2 into the light guide 79a, to a second light exit surface 87a2 of the scintillator arrangement 11a or of the light guide 79a. The surfaces of the light guide 79a that are different from the light exit surface 87a2 and a contact surface to the second scintillator body 77a2 are again provided with an electrically conductive and light-reflecting layer, which is not shown in FIG. 3.

The second scintillator body 77a2 is attached to an electrically conductive tube 71a, which provides the beam tube 5a, and is electrically connected thereto, such that the electrically conductive surfaces of the second scintillator body 77a2 are at an electric potential U4, which is equal to the potential U2 of the beam tube 5a. The first scintillator body 77a1 is attached to the light guide 79a via a holder piece 123 in such a way that the two light exit surfaces 87a1 and 87a2 are spaced apart from each other. The surface of the holder piece 123 facing the axis of symmetry is electrically conductive. The electrically conductive surfaces of the first scintillator body 77a1 are electrically conductively connected to the electrically conductive surfaces of the light guide 79a, of the holder piece 123 and of the second scintillator body 77a2, with the result that the first scintillator body 77a1 is also at the potential U4, which is equal to the potential U2 of the beam tube 5a. The two scintillator bodies 77a1 and 77a2 and the light guide 79a also carry electrically conductive coatings on their surfaces, similar to the scintillator body and the light guide of the embodiment shown in FIG. 2, which may be reflective or light-transmissive, but which are not shown in FIG. 3.

The detector arrangement 13a comprises a light detector 105a, which has a printed circuit board 107a and a first light detector 109a1 and a second light detector 109a2, which are arranged side-by-side in the cross section containing the axis of symmetry 39a. These light detectors 109a1 and 109a2, which are separated in the radial direction, can also be referred to as radial detector segments. The first light detector 109a1, which in this embodiment is a first semiconductor detector, provides a first light entry surface 111a1 of the detector arrangement 13a, and the second light detector 109a2, which in this embodiment is a second semiconductor detector, provides a second light entry surface 111a2 of the detector arrangement 13a.

Furthermore, it is in particular possible that, viewed over the circumference around the axis of symmetry 39a, a plurality of mutually separate semiconductor detectors are provided. These then correspond to separate light detectors of which each has a terminal for outputting detection signals and for inputting them to the controller 16.

Measured along the axis of symmetry 39a, the distance between the first light entry surface 111a1 and the object plane 41a and the distance between the second light entry surface 111a2 and the object plane 41a are both greater than the distance between the first scintillator body 77a1 and the object plane 41a and also greater than the distance between the second scintillator body 77a2 and the object plane 41a. The at least one scintillator body 77a1 and/or 77a2, viewed along the axis of symmetry 39a, is thus arranged between the at least one light entry surface 111a1 and 111a2 and the object plane 41a.

The printed circuit board 107a comprises an electric circuit to operate the two light detectors 109a1 and 109a2 and to output detection signals generated by the light detectors to a controller of the electron microscope la via a terminal 63a.

The light exiting from the two light exit surfaces 87a1 and 87a2 into a vacuum space 112a is reflected via a mirror surface 103a of a mirror 101a, mounted on the pole end 35a, towards the two light entry surfaces 111a1 and 111a2 of the detector arrangement 13a. In this case, the mirror surface 103a in the plane containing the axis of symmetry 39a again has an elliptical shape, which is part of an ellipse with two focal points 115aand 117a, which are spaced apart. The one focal point 115a is arranged approximately between the two light exit surfaces 87a1 and 87a2 of the scintillator arrangement 11a. The other focal point 117a is arranged approximately between the two adjacent light entry surfaces 111a1 and 111a2 of the detector arrangement 13a, which are arranged side by side. This leads to the situation in which the light emerging from the first light exit surface 87a1 is reflected to a greater part towards the first light entry surface 111a1 so as to be detected by the first light detector 109a1 than to the second light entry surface 111a2. Light rays 89a1 and 113a1 are examples of this beam path. In this exemplary embodiment, the two light entry surfaces 111a1 and 111a2 are arranged laterally offset from each other. In other embodiments, they may also be offset relative to each other viewed in the direction of the axis of symmetry 39a.

Accordingly, light that emerges from the second light exit surface 87a2 is reflected via the mirror surface 103a to a greater part to the second light entry surface 111a2 so as to be detected by the second light detector 109a2 than to the first light entry surface 111a1. Light rays 89a2 and 113a2 are examples of this beam path.

Detection signals generated by the first light detector 109a1 are thus mainly due to electrons that are incident on the first scintillator body 77a1, and detection signals that are detected by the second light detector 109a2 are thus mainly due to electrons that are incident on the second scintillator body 77a2. Since electrons that start from the object plane 41a at different angles relative to the axis of symmetry 39a and/or with different kinetic energies are incident on the two scintillator bodies 77a1 and 77a2, it is possible to use the detection system, which has two scintillator bodies 77a1 and 77a2 arranged side-by-side and two light detectors arranged side-by-side in the plane containing the axis of symmetry 39a, to discriminate detected electrons with regard to their exit angles, relative to the axis of symmetry 39a, from the object 31 and/or with regard to their kinetic energy upon exit from the object 31.

The scintillator arrangement 11a with its two scintillator bodies 77a1 and 77a2 and the light guide 79a and holder piece 123 is arranged so that no light ray, starting from the intersection point 121a of the axis of symmetry 39a with the object plane 41a can pass directly to one of the two light entry surfaces 11a1, 11a2. Therefore, the two light detectors 109a1 and 109a2 do not detect any light rays that are generated by the electron beam at the object.

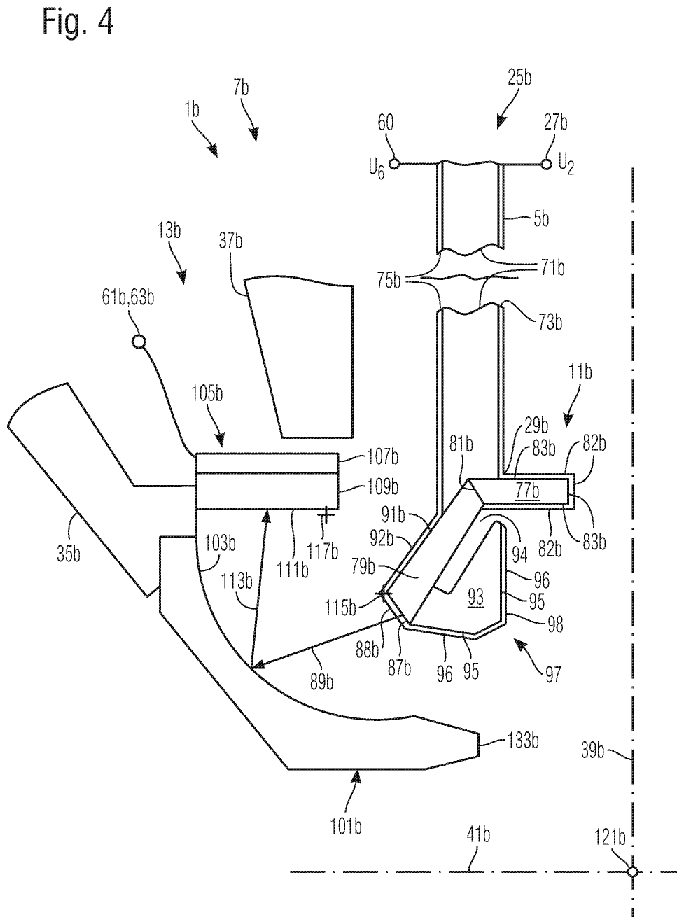

FIG. 4 is a detailed view of an electron microscope 1b corresponding to FIG. 2, according to a third embodiment. In FIG. 4, components which correspond to the first and the second embodiment in terms of their structure or function are provided with the same reference signs as in FIGS. 1 to 3, although a lowercase “b” has been added to the components of the third embodiment.

The electron microscope 1b is very similar to the electron microscope 1 of the first embodiment, in that a scintillator arrangement 11b comprises a scintillator body 77b and the light generated in the scintillator body 77b is guided via a light guide 79b to a light exit surface 87b of the scintillator arrangement 11b. Light 89b emerging from the light exit surface 87b is reflected via a mirror 101b having an elliptical mirror surface 103b in the cross section of FIG. 4 onto a light entry surface 111b of a detector arrangement 13b. The reflected light 113b penetrates into a semiconductor detector 109b via the light entry surface 111b in order to generate detection signals there. These are processed by an electric circuit on a printed circuit board 107b, amplified, shaped and output via a terminal 63b.

The electron microscope 1b differs substantially from the electron microscope 1 of the first embodiment with regard to the potential U4 of the scintillator body 77b and in that close to the scintillator body 77b an additional ring electrode 97 is provided, which contributes to the shaping of the electric fields which determine the focusing of the particle beam and determine the trajectories of the electrons which are generated by the particle beam at the object and are detected by detectors.

The scintillator arrangement 11b is mounted near a lower end 29b of the beam tube 5b, outside the latter. The beam tube 5b, as the electrode surrounding the electron beam, is formed in the region of its lower end 29b as an electrically conductive layer 73b, which is mounted on the inner wall of a tube 71b made of an electrically insulating material. The electrically conductive layer 73b is electrically connected to a terminal 27b, which supplies the beam tube 5b with the electric potential U2, which accelerates the electrons of the electron beam before they enter the beam tube 5b at its upper end 25b. The outer wall of the insulating tube 71b is provided with a conductive layer 75b, which is connected to a terminal 60 for supplying an electric potential U7. The terminal 60 may be provided in the illustration of FIG. 1, for example, in a region between the upper end 25b of the beam tube 5b and the objective lens 7b.

The scintillator body 77b is attached directly below the lower end 29b of the beam tube 5b to the insulating tube 71b. The scintillator body 77b has the shape of a torus with plane-parallel main surfaces, with the torus extending around the axis of symmetry 39b. The light guide 79b is optically coupled to a radially outer surface 81b of the scintillator body 77b. Other surfaces 83b of the scintillator body 77b are provided with an electrically conductive reflective layer 82b, such as a metal layer, so that light generated in the scintillator body 77b is reflected inside until it passes into the light guide 79b via the surface 81b. The electrically conductive, reflective layer 82b is electrically conductively connected to the electrically conductive layer 73b, which forms the beam tube 5b, such that the potential U4 of the scintillator body 77b is equal to the potential U2 of the beam tube 5b.

A surface 91b of the light guide 79b is provided with a layer 92b which is electrically conductive and in particular can also be light-reflective in order to avoid a possible exit of light from the light guide 79b through this surface 91b. The electrically conductive layer 92b on the surface of the light guide 79b is electrically conductively connected to the layer 75b and is thus at the potential U7. The light exit surface 87b of the light guide 79b is provided with an electrically conductive, light-transmissive layer 88b, which is electrically conductively connected to layer 92b.

A ring-shaped body 93 made of an electrically insulating material is attached to the light guide 79b in the region of an end of the light guide 79b remote from the scintillator body 77b. The ring-shaped body 93 is designed such that it extends inwardly, towards the axis of symmetry 39b, and towards the scintillator body 77b, with a gap 94 remaining between the light guide 79b and the ring-shaped body 93 in the region of an end of the light guide 79b close to the scintillator body 77b.

Surfaces 95 of the ring-shaped body 93, which do not adjoin the gap 94, are provided with an electrically conductive layer 96, which is electrically conductively connected to the electrically conductive, light-transmissive layer 88b on the light exit surface 87b of the scintillator arrangement 11b. The surface of the ring-shaped body 93 covered with the layer 96 is thus also at the potential U7 and forms the ring electrode 97, through which the electron beam passes through an opening 98 symmetrical with respect to the axis of symmetry 39b. The potential U7 of the ring electrode 97 can be different from the potential U2 of the beam tube 5b and from the potential U4 of the scintillator body 77b, which in this example is equal to the potential U2.

Viewed along the axis of symmetry 39b, the ring electrode 97 lies between the scintillator body 77b and the object plane 41b and between the scintillator body 77b and a ring electrode 131b, which is formed by the mirror 101b and through which the electron beam passes through an opening 133b in the mirror 101b.

According to one example, the potential U2 of the beam tube 5b is equal to the potential U4 of the scintillator body 77b and equal to 8 kV, while the potential U7 of the ring electrode 93 is equal to 9 kV. The potential U1 of the object can be the ground potential 0 V or it can lie in the range from −1 kV to +1 kV. The potential U3 of the pole ends 35b or 37b of the objective lens 7b can be equal to the potential U1 of the object or differ therefrom, for example, by a few kilovolts. The potential U5 of the light detector 13b can be the ground potential 0 V.

With the electron microscope described here it is possible to provide a detection system that can efficiently detect backscatter electrons, since scintillator bodies that generate light from electrons are arranged close to the object plane. Furthermore, the light generated by the scintillator arrangement can be efficiently detected by the detector arrangement, which is arranged within the objective lens and also takes up little installation space. This also allows the objective lens to be designed in such a way that it has a conical shape with an acute cone angle in order to examine large objects with a great tilt relative to the axis of symmetry. This conical shape with the acute cone angle can be illustrated via a plane 122, shown in FIG. 1, which passes through the intersection point 121 between the axis of symmetry 39 and the object plane 41 and which merely touches but does not intersect an outer edge of the magnetic objective lens 7. The objective lens 7 can be designed such that an angle between the plane 122 and the axis of symmetry 39, which corresponds to approximately half the cone angle of the conical shape of the objective lens 7, is less than 50°. With regard to this angle, the illustration of FIG. 1 is not applicable, since FIG. 1 is designed with regard to the clear illustration of the components of the objective lens 7 and does not exactly reproduce the geometric relations.

1. An electron beam microscope, comprising:
an electron beam source configured to generate an electron beam;
a beam tube comprising first and second ends, the beam tube configured so that the electron beam enters the beam tube at the first end and emerges from the beam tube at the second end;
a magnetic objective lens configured to focus the electron beam in an object plane, the magnetic objective lens comprising a solenoid and a yoke, the yoke having first and second pole ends, each of the first and second pole ends extending around an axis of symmetry of the magnetic objective lens;
an object holder configured to hold an object in the object plane;
a scintillator arrangement comprising a scintillator body configured to generate light from electrons coming from the object plane, the scintillator arrangement comprising a light exit surface configured so that the light generated by the scintillator body enters a vacuum space from the scintillator arrangement;
a detector arrangement comprising a light detector configured to convert light generated by the scintillator arrangement into electrical signals, the detector arrangement comprising a light entry surface through which the light enters the detector arrangement from the vacuum space; and
a potential supply system configured to supply: i) the object holder with a potential U1; ii) the beam tube with a potential U2; iii) the first pole end and/or the second pole end with a potential U3; iv) the scintillator body with a potential U4; the light detector with a potential U5, such that:
$$( U 2 - U 5 ) \geq 5000 V ;$$
$$( U 4 - U 1 ) \geq 0.1 * ( U 2 - U 1 ) ;$$
$$\vert U 4 - U 5 \vert \geq 0.1 * ( U 2 - U 1 ) ; and$$
$$\vert U 3 - U 5 \vert \leq 0.3 * ( U 2 - U 1 ) .$$

2. The electron beam microscope of claim 1, further comprising a mirror comprising a light-reflecting mirror surface configured to reflect light emerging from the exit surface of the scintillator arrangement towards the light entry surface of the detector arrangement.

3. The electron beam microscope of claim 2, wherein the mirror surface has at least partially a rotationally symmetrical shape with respect to the axis of symmetry.

4. The electron beam microscope of claim 2, wherein, viewed in a cross section containing the axis of symmetry, the mirror surface has a shape which is part of an ellipse.

5. The electron beam microscope of claim 4, wherein:
the ellipse has a first and second focal points;
the first focal point is closer to the light exit surface than to the light entry surface; and
the second focal point is closer to the light entry surface than to the exit surface.

6. The electron beam microscope of claim 2, wherein:
viewed in a cross section containing the axis of symmetry, the first pole end is closer to the beam tube than is the second pole end; and
the second pole end supports the mirror.

7. The electron beam microscope of claim 2, wherein at least a part of the mirror surface is closer to the object plane than is the light exit surface of the scintillator arrangement.

8. The electron beam microscope of claim 1, wherein viewed in a cross section containing the axis of symmetry:
the scintillator arrangement comprises two side-by-side scintillator bodies; and
the detector arrangement comprises two side-by-side light detectors.

9. The electron beam microscope of claim 1, wherein the scintillator arrangement comprises a guide optically coupled to the scintillator body to define the light exit surface.

10. The electron beam microscope of claim 9, wherein a surface of the light guide, which is different from the light exit surface and from a surface which is coupled to the scintillator body, comprises a metal layer.

11. The electron beam microscope of claim 1, wherein a surface of the scintillator body comprises an electrically conductive layer.

12. The electron beam microscope of claim 1, wherein the light exit surface comprises an electrically conductive and light-transmissive layer.

13. The electron beam microscope of claim 1, wherein the first pole end supports the light detector.

14. The electron beam microscope of claim 13, wherein:
viewed in a cross section containing the axis of symmetry, the first pole end is closer to the beam tube than is the second pole end; and
the second pole end supports the light detector.

15. The electron beam microscope of claim 1, wherein, viewed along the axis of symmetry, the scintillator body is between the light entry surface and the object plane.

16. The electron beam microscope of claim 1, wherein the scintillator body is supported by the beam tube or a carrier of the beam tube.

17. The electron beam microscope of claim 1, wherein the scintillator body is electrically insulated from the beam tube, and |U2−U4|≥0.1*(U2−U1).

18. The electron beam microscope of claim 1, further comprising an electron detector configured to detect electrons coming from the object plane that have entered the second end of the beam tube.

19. The electron beam microscope of claim 1, further comprising a beam deflector configured to scan a location of incidence of the electron beam on the object plane over the object plane,
wherein, viewed along the axis of symmetry, the beam deflector is between the electron detector and the scintillator body.

20. The electron beam microscope of claim 1, wherein the detector arrangement comprises a plurality of light detectors distributed around the axis of symmetry.

21-29. (canceled)
